(19) United States
(12) Patent Application Publication
(10) Pub. No.: US 2007/0179729 A1
(43) Pub. Date: Aug. 2, 2007

(54) NUMERICAL DATA PROCESSING DEDICATED TO AN INTEGRATED MICROSPETROMETER

(76) Inventors: Roman Z. Morawski, Quebec (CA); Michal Wisniewski, Quebec (CA); Andrzej Barwicz, Quebec (CA)

Correspondence Address: BLAKE, CASSELS & GRAYDON LLP, BOX 25, COMMERCE COURT WEST, 199 BAY STREET, SUITE 2800, TORONTO, ON, M5L 1A9, CA

(21) Appl. No.: 11/565,865

(22) Filed: Dec. 1, 2006

Related U.S. Application Data
(63) Continuation of application No. 11/071,884, filed on Mar. 4, 2005, now abandoned.
(60) Provisional application No. 60/549,562, filed on Mar. 4, 2004.

(51) Int. Cl. G01D 18/00; G01R 35/00; G01C 19/00; G06F 19/00

(52) U.S. Cl. 702/104; 702/106

(57) ABSTRACT

A method and apparatus for obtaining higher resolution spectral data on lower-resolution spectral data provided by a spectrometric transducer is described. The method includes calibrating the spectrometric transducer to produce results for a reconstruction of spectra using the results, and processing the lower-resolution spectra data using a set of numerical algorithms dedicated to an integrated micro-spectrometers associated with the spectrometric transducer and using the results of calibrating to provide the higher resolution spectra data. The apparatus utilizes the method.

This application is a continuation of U.S. patent application Ser. No. 11/071,884 filed on Mar. 4, 2005 which claims priority from U.S. Provisional Patent Application No. 60/549,562 filed on Mar. 4, 2004.

### BACKGROUND OF THE INVENTION

A miniature lowest integrated spectrophotometer (an integrated microspectrometer) may be used in a number of applications, such as industrial monitoring and quality control, medical and pharmaceutical testing, plant growth characterization, environmental and pollution monitoring, food control, and light source testing. Process control, such as in chemical plants, in the semiconductor industry, in dye works and in electroplating operations, is another area taking advantage of higher spectral resolution and measurement accuracy of spectrophotometry. Other applications that may require simultaneous measurement of several spectra include multiangle color measurement of paint work, continual real-time monitoring of water quality, color control in color printers and digital cameras, olive-oil and wine quality assessment, non-invasive blood glucose detection, fruits analysis, cosmetics and drug analysis, and security-related equipment.

Spectrophotometry may be considered as an analytic technique concerned with the measurement and characterization of the interaction of light energy with matter. Spectrophotometry may involve working with instruments designed for this purpose, referred to by some as spectrophotometers, and corresponding methods of interpreting the interaction both at the fundamental level and for practical analysis. The distribution of light energy, absorbed or emitted by a sample of a substance under study, may be referred to as its spectrum. If energy of ultraviolet (UV), visible (Vis) or infrared (IR) light is used, the corresponding spectrum may be referred to as a light spectrum.

A spectrophotometer may have a resolution associated with its design or implementation affecting resolution of measured spectra. As is well understood by those of skill in the art of spectrometry, a required resolution for UV and a required resolution for IR spectral imaging may be different. Further, the terms high-resolution and low-resolution are related to an imaged spectral band or to wavelengths of light within the imaged band. For a broadband spectrometer, either graduated spectral resolution or a spectral resolution sufficient to properly image each band may be used.

Interpretation of spectra may provide fundamental information at atomic and molecular energy levels. For example, the distribution of species within those levels, the nature of processes involving change from one level to another, molecular geometries, chemical bonding, and interaction of molecules in solution may all be studied using spectrum information. Comparisons of spectra to provide a basis for the determination of qualitative chemical composition and chemical structure, and quantitative chemical analysis is described in detail in Parker S. (Ed.): McGraw-Hill Encyclopedia of Chemistry, McGraw-Hill, 1983, which is hereby incorporated by reference.

Known techniques for processing data from spectrum analyzers tend to provide inadequate quality of spectrum estimation for lower-cost spectrophotometers.

U.S. Pat. No. 5,712,710 for example, describes a probe for use in measuring the concentration of a specific metal ion dissolved in liquid. The device suffers from known problems of probe miniaturization. Either the bandwidth of the spectrometer is narrow to accommodate a small probe size, the quality of the spectral imaging is poor, or the optical processing components are large and costly. The described device comprises a hand-held processing unit coupled to the probe. The processing unit is programmed to calculate and display the concentration of a specific material. In this probe neither the photodetector nor the processing unit is integrated with the light diffraction structure. Further, the use of poor resolution in imaging the spectrum tends to be unacceptable for most applications when using such a probe.

U.S. Pat. No. 5,020,910 describes a method of forming a light diffraction structure directly over a photodetector. The described device requires external electronic circuitry to obtain a useful spectrum of light and the spectral resolution is very high in comparison to that of existing conventional spectrometers.

U.S. Pat. No. 5,731,874 describes a spectrometer with an integrated photodetector. The described device is sensitive only to particular spectral lines and thus tends to be useful only over a narrow spectral range.

Therefore, there exists a need for a method and apparatus to alleviate some disadvantages in the prior art.

Known laboratory spectrophotometers may perform acceptably for some applications, but they are typically bulky and costly. It would be desirable to provide lower-cost integrated micro-spectrophotometer capable of determining the spectral characteristics of the optical signals

### SUMMARY OF THE INVENTION

In a broad aspect of the present invention, there is a family of integrated microspectrometers whose principle of functioning is based on the subsequent use of a spectrometric transducer and a computing circuit, including a digital signal processor.

In another broad aspect of the present invention, there is provided a method for obtaining higher-resolution spectral data on the lower-resolution spectral data provided by the spectrometric transducer. The method comprises a set of numerical algorithms, dedicated to integrated microspectrometers of this type, designed for calibration of those devices and for reconstruction of spectra using the results of calibration.

In another broad aspect of the present invention, there is provided a method for obtaining higher resolution spectral data on lower-resolution spectral data provided by a spectrometric transducer. The method comprises: calibrating the spectrometric transducer to produce results for a reconstruction of spectra using the results; and processing the lower-resolution spectra data using a set of numerical algorithms dedicated to an integrated micro-spectrometers associated with the spectrometric transducer and using the results of calibrating to provide the higher resolution spectra data.

### BRIEF DESCRIPTION OF THE DRAWINGS

An embodiment of the present invention will now be described by way of example only with reference to the accompanying drawings, in which:

FIG. 1 is a schematic diagram of an optical spectrum measurement instrument.

FIG. 2 is a flow diagram of a procedure for resampling gₙ(λ).

FIG. 3 is a flow diagram of a procedure for obtaining the final result of a spectrum estimation.

### DETAILED DESCRIPTION OF THE INVENTION

The description which follows, and the embodiments described therein, are provided by way of illustration of an example, or examples, of particular embodiments of the principles of the present invention. These examples are provided for the purposes of explanation, and not limitation, of those principles and of the invention. In the description, which follows, like parts are marked throughout the specification and the drawings with the same respective reference numerals.

A way to provide lower-cost integrated micro-spectrophotometer capable of determining the spectral characteristics of the optical signals is harness more of the computing power of microprocessors and other processors. Aspects of such a design paradigm shift is described in U.S. Pat. No. 6,002,479 Apparatus and Method for Light Spectrum Measurement and U.S. Pat. No. 5,991,023 Method of Interpreting Spectrometric Data, the specifications of which are hereby incorporated by reference. Specific numerical techniques may be applied in utilizing the computational power of processors to ensure a required precision and high dynamic range of a spectrophotometer instrument as described below.

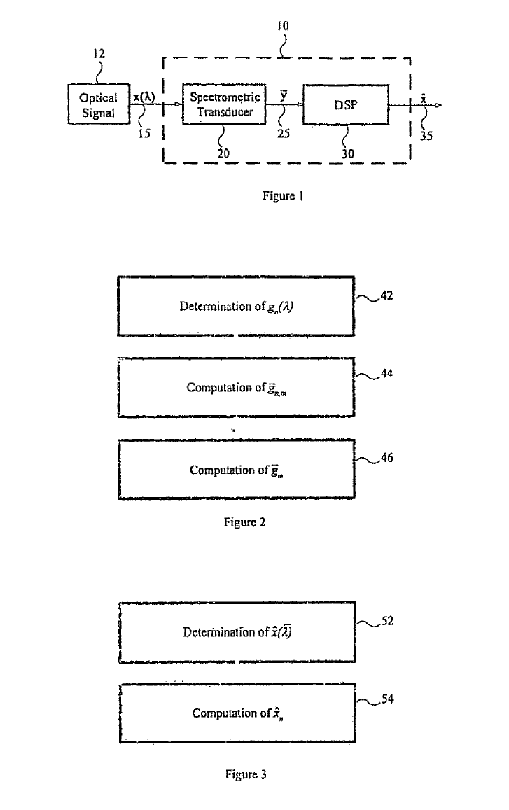

Although spectrometric transducers are used in a variety of devices, for the purpose of the following discussion it will be described in the context of an integrated microspectrometer. As illustrated in FIG. 1, an integrated microspectrometer 10 basically consists of a spectrometric transducer 20 and a digital signal processor (DSP) 30. The spectrometric transducer 20 converts an optical signal 12 into a digital signal \tilde{y} representative of the spectrum x(λ) 15 of that optical signal 12. The spectrometric transducer 20 receives an analog optical input 24 and provides an output through N digital electrical outputs, typically photodiodes that convert an incident optical signal into a corresponding electrical signal. In practice, the spectrometric transducer 20 could be a dedicated optoelectronic transducer or a complete instrument such as a spectrum analyzer with fixed measurement parameters such as wavelength range, optical resolution, sensitivity, etc.

Assumptions and Notations

The spectrometric transducer 20 output-related discretization of the wavelength axis is defined by the sequence {λₙ} such that
λₘᵢₙ=λ₁<λ₂< . . . λ_{N-1}<λ_{N}=λₘₐₓ Equation 1
where N is the number outputs of the spectrometric transducer 20. Thus, the average interval between the consecutive wavelength values is:

$$Δλ = \frac{{λ}_{max} - {λ}_{min}}{N - 1}$$

The spectrometric transducer 20 calibration-related discretization of the wavelength axis is defined by the formula:
λ′ₘ=λ′ₘᵢₙ+(m−1)Δλ′ m=1, . . . , M Equation 2
where M>>N is the number of discretization points, i.e. of the position of the tunable monochromators used for calibration, and:

$${Δλ}^{′} = \frac{{λ}_{max}^{′} - {λ}_{min}^{′}}{M - 1}$$

$$with {λ}_{min}^{′} ≅ {λ}_{min} and {λ}_{max}^{′} ≅ {λ}_{max} .$$

It is assumed that the spectrum x(λ) 15 of the analyzed optical signal 12, i.e. light intensity vs. wavelength, may be adequately approximated by a known function \hat{x}(λ; p) with unknown parameters p=[p₁ . . . p_{K}]^{T}. A sequence of samples of x(λ) 15 is a particular case of such a vector (due to the Shannon theorem). In this case:

$$p ≡ x = {[ {x}_{1} … {x}_{K} ]}^{T} ≡ {[ x ( {λ}_{1}^{″} ) … x ( {λ}_{K}^{″} ) ]}^{T} \\ where \text{:} \\ {λ}_{k}^{″} = {λ}_{min}^{″} + ( k - 1 ) Δ {λ}^{″} for k = 1 , … , K \\ with \\ {λ}_{min}^{″} ≅ {λ}_{min} and {λ}_{max}^{″} ≅ {λ}_{max} , \\ and \text{:} \\ Δ {λ}^{″} = \frac{{λ}_{max}^{″} - {λ}_{min}^{″}}{K - 1} . \qquad Equation 3$$

Mathematical Model of the Data

An adequate implicit model of the data {\tilde{y}ₙ|n=1, . . . , N} 25 acquired at the output of the spectrometric transducer 20 has the form:

$$F ( {\hat{y}}_{n} ; {α}_{n} ) = {\int }_{- Δ λ / 2 ρ}^{+ Δ λ / 2 ρ} [ {\int }_{- ∞}^{∞} g ( {λ}_{n} + {λ}^{′} , λ ) x ( λ ) ⅆ λ ] ⅆ {λ}^{′} \\ for n = 1 , … , N \qquad Equation 4$$

where F(∞; αₙ) is a known function with unknown parameters αₙ=[α₁ . . . α_{Q}]^{T}, that models the inverse “static” characteristic of the spectrometric transducer 20 with respect to the n th photodiode (n=1, . . . , N); g(λ′, λ) is the impulse response of the optical part of the spectrometric transducer 20, and ρ is the ratio of the distance between two consecutive photodiodes and the photodiode width. The above model may be given a simpler form:

$$F ( {\hat{y}}_{n} ; {α}_{n} ) = {\int }_{- ∞}^{+ ∞} {g}_{n} ( {λ}_{n} - λ ) x ( λ ) ⅆ λ \\ for n = 1 , … , N \qquad Equation 5$$

by introducing the functions:

$${g}_{n} ( λ ) = {\int }_{- Δ λ / 2 ρ}^{+ Δ λ / 2 ρ} g ( {λ}_{n} + {λ}^{′} , {λ}_{n} - λ ) ⅆ {λ}^{′} \\ for n = 1 , … , N \qquad Equation 6 a$$

being the normalized responses of the photodiodes. Each of these functions is the response of the spectrometric transducer 20, measured at the output of the nth photodiode, to a sweeping monochromator producing an optical signal whose spectrum may be adequately modeled with x(λ)≡δ(λ−l) where l is moving from λₘᵢₙ to λₘₐₓ. This response is assumed to be centered around λ=0, and—thus—satisfying the condition:

$${\int }_{- ∞}^{0} {g}_{n} ( λ ) ⅆ λ = {\int }_{0}^{+ ∞} {g}_{n} ( λ ) ⅆ λ = 0.5 \\ for n = 1 , … , N \qquad Equation 6 b$$

Under this assumption, the response of the model to the optical signal with a flat spectrum (i.e. constant as x varies), x(λ)=X^{f}, satisfies the following equations:
F(ŷₙ; αₙ^{f})=X^{f} for n=1, . . . , N Equation 7
and its response to a monochromatic signal, x(λ)=Xδ(λ−l), the equations:
F(ŷₙ; αₙ)=Xgₙ(λₙ−l) for n=1, . . . , N Equation 8
Calibration of the Spectrometric Transducer

Numerical data processing dedicated to the integrated microspectrometer 10 comprises reference data processing aimed at calibration of the spectrometric transducer 20, and estimation of the spectrum of an analyzed optical signal or of its parameters. Calibration-related data processing may be performed by an external computer, while estimation of parameters must rely on the internal DSP 30.

It follows from Equation 7 that the parameters αₙ corresponding to the n th wavelength (n=1, . . . , N) may be estimated during calibration from the responses {\tilde{y}_{n,q}^{f,cal}} of the spectrometric transducer 20 to Q flat-spectrum signals:
x(λ)=x_{q}^{f,cal}(λ)≡X_{q}^{f} for q=1, . . . ,Q Equation 9
by solving a set of algebraic equations:
\hat{α}ₙ=arg_{α}{F(\tilde{y}_{n,q}^{f,cal};α)=X_{q}^{f}|q=1, . . . ,Q} n=1, . . . ,N Equation 10
Accordingly, α may be obtained for each n.

On the other hand, the estimation of the functions gₙ(λ) could be based on the reference data:
{\tilde{y}_{n,m}^{cal}|n=1, . . . ,N} Equation 11
acquired at the spectrometric transducer 20 output excited by a broadband source followed by a tunable monochromator:
xₘ^{cal}(λ)=Xₘδ(λ−λ′ₘ) for m=1, . . . ,M Equation 12

If the data are normalized before processing:
\tilde{y}_{n,m}^{cal}F(\tilde{y}_{n,m}^{cal};\hat{α}ₙ)/Xₘ for n=1, . . . ,N; m=1, . . . ,M Equation 13
then their model defined by Equation 8 takes on the form:
ŷ_{n,m}^{cal}=gₙ(λₙ−λₘ) for n=1, . . . , N; m=1, . . . ,M Equation 14

This formula suggests that, for any fixed value of n, one may obtain a discrete representation of gₙ(λ) by direct smoothing of the data {\tilde{y}_{n,M-m+1}^{cal}|m=1, . . . ,M}:
ĝ_{n,m}≈gₙ(λₙ−λ_{M-m+1}) for m=1, . . . ,M Equation 15

This sequence has to be properly centered by estimation of λₙ. First, the interval └λ_{M-m*},λ_{M-m*+1}┘, the wavelength λₙ belongs to, should be identified:

$$\begin{matrix}{m}^{*} = {arg}_{m} \{ {S}_{n , m} \leq 0.5 {S}_{n , {m}_{max}} \leq {S}_{n , m + 1} \} \\ with \text{:} & Equation 16 \\ {S}_{n , m} = {\sum }_{μ = {m}_{min}}^{m} {\hat{g}}_{n , μ} & Equation 17\end{matrix}$$

where mₘᵢₙ and mₘₐₓ are indices delimiting the central part of the main lobe of the estimate {ĝ_{n,m}} of the spectrometric transducer 20 response corresponding to the n th wavelength value. Then, an estimate \hat{λ}ₙ of λₙ may be found by means of linear interpolation based on two points: [symbol]
λ_{M-m*},S_{n,m*+1} [symbol] and [symbol] λ_{M-m*+1},S_{n,m*} [symbol] Equation 18

The result of this interpolation is:

$$\begin{matrix}centre of g {\hat{λ}}_{n} = {w}_{n} {λ}_{M - {m}^{*}} + ( 1 - {w}_{n} ) {λ}_{M - {m}^{*} + 1} \\ with \text{:} & Equation 19 \\ {w}_{n} = \frac{{S}_{n , {m}^{*} + 1} - 0.5 {S}_{n , {m}_{max}}}{{\hat{g}}_{n , {m}^{*} + 1}} & Equation 20\end{matrix}$$

which represents the centre of the response for a given output. As noted above, the calibration α, to obtain α and g may be done on a computer.
Estimation of the Spectrum and/or its Parameters

Using the results of the calibration, it is then possible to estimate spectrum using the DSP 30. It is assumed that the data for parameter estimation are normalized in the following way before processing:
\tilde{z}ₙ=F(\tilde{y}ₙ;\hat{α}ₙ) for n=1, . . . ,N Equation 21

Consequently, the problem of spectrum estimation to be solved is non-stationary but linear, and the parameterized model of the normalized data, resulting from of Equation 5, assumes the form:
\hat{z}ₙ(p)=[gₙ(λ)*\hat{x}(λ;p)]_{λ=λ}_{ₙ} for n=1, . . . ,N Equation 22

A wide class of variational methods for spectrum estimation may be defined using this model:
\hat{p}=argₚinf{∥\tilde{z}−\hat{z}(p)∥_{w}|pεP} with q=2 or ∞ Equation 23
where:
\tilde{z}=[\tilde{z}₁ . . . \tilde{z}_{N}]^{T} Equation 24
\hat{z}(p)=[\hat{z}₁(p) . . . \hat{z}_{N}(p)]^{T} Equation 25
and P is a set of optimization constraints.

Numerous sequential filtering algorithms may be directly applied or adapted for solving the problem of spectrum estimation on the basis of raw measurement data modeled by Equation 22, in particular as described in the attached bibliography:
direct methods [1], [2], [3], [4], [5];
spline-based recursive methods [6], [11];
Kalman-filter-based methods [7], [8], [9], [10], [11];
polynomial-filter-based methods [12], [13], [14], [15];
rational-filter-based methods [16], [17], [18];
Cauchy-filter-based and neural-network-based methods [19], [20], [21].

However, under certain conditions, deconvolution methods may be also applied for this purpose. Three viable options will now be described: transformation of the wavelength axis, interpolation of multiple solutions and linear stationary solution.

Transformation of the Wavelength Axis

If the functions gₙ(λ) differ in height to width ratio but do not differ significantly in shape, then deconvolution methods may be used for the estimation of the spectrum after appropriate transformation of the λ-axis:
λ̅=T(λ) for λε[λₘᵢₙ, λₘₐₓ] Equation 26

This transformation should be based on the height-to-width ratios characterizing those functions: r₁, . . . , r_{N}, and should convert a non-stationary problem of spectrum reconstruction into a stationary one; thus, it should satisfy the following conditions:
T′(λₙ)=arₙ+b for n=1, . . . , N Equation 27
T(λ₁)=ar₁+b Equation 28
T(λ_{N})=ar_{N}+b Equation 29

Assuming that T(λ) is a known function, e.g. a spline function, with N free parameters, the above set of N+2 algebraic equations can be solved with respect to a, b, and those parameters. Consequently, the set of transformed wavelength values can be determined:
λ̅ₙ=T(λₙ) for n=1, . . . ,N Equation 30

They are necessary for resampling of the functions gₙ(λ) and computing { g̅ₘ}, which is the average of the resampling results. It should be noted that the dispersion in the resampled functions may be partially compensated for by appropriate adjustment of the function F(\tilde{y}ₙ;\hat{α}ₙ).

The procedure for resampling gₙ(λ), represented by a sequence {g_{n,m}|m= . . . , −1, 0, 1, . . . } is depicted by the flow chart shown in FIG. 2. The sequence of steps composing the procedure is indicated by the sequence of blocks 42 to 46.

In block 42 the procedure starts by determining g̅ₙ( λ̅) by smoothing approximation or interpolation of the sequence {g_{n,m}, λ̅ₙ₊ₘ|m= . . . ,−1,0,1, . . . }.

Then at block 44, { g̅_{n,m}= g̅ₙ( λ̅ₙ+mΔλ)|m= . . . −1,0,1, . . . } is computed.

Following which, at block 46,

$$\{ {\overline{g}}_{m} = \frac{1}{N} {\sum }_{n = 1}^{N} {\overline{g}}_{n , m} \vert m = … , - 1 , 0 , 1 , … \}$$

is computed.

Assuming that the sequence { x̅ₙ|n=1, . . . ,N} is the result of a deconvolution, obtained on the basis of {\tilde{y}ₙ} and {\tilde{g}ₘ}, the procedure for obtaining the final result of the spectrum estimation is depicted by the flow chart shown in FIG. 3. The sequence of steps composing the procedure is indicated by the sequence of blocks 52 to 54.

In block 52 the procedure starts by determining \hat{x}( λ̅) by smoothing approximation or interpolation of the sequence { x̅ₙ, λ̅ₙ|n=1, . . . , N}.

Then, at block 54, {\hat{x}ₙ=\hat{x}(λₙ)|n=1, . . . ,N} is computed.

Interpolation of Multiple Solutions

An alternative methodology enabling the use of deconvolution algorithms for solving non-stationary problems of spectrum reconstruction may be based on the use of different responses gᵢ(λ) for processing the data in consecutive overlapping intervals.

Assuming that:
each interval contains ΔN data;
the intervals are determined by the indices Nᵢ₊₁=Nᵢ+ΔN;
gᵢ(λ) is the response used for deconvolution for n= . . . ,Nᵢ₋₁, . . . Nᵢ, . . . , Nᵢ₊₁, . . . ;
{\hat{x}ₙ⁽ⁱ⁾} is the result of deconvolution performed with gᵢ(λ).

Then the linearly-interpolated final result of the deconvolution for n=Nᵢ₋₁, . . . Nᵢ, . . . ,Nᵢ₊₁ may be calculated according to the formula:

$${\hat{x}}_{n} = \{ \begin{matrix}\frac{{N}_{i} - n}{Δ N} {\hat{x}}_{n}^{( i - 1 )} + \frac{n - {N}_{i - 1}}{Δ N} {\hat{x}}_{n}^{( i )} & for n = {N}_{i - 1} + 1 , ... , {N}_{i} \\ \frac{{N}_{i + 1} - n}{Δ N} {\hat{x}}_{n}^{( i )} + \frac{n - {N}_{i}}{Δ N} {\hat{x}}_{n}^{( i + 1 )} & for n = {N}_{i} + 1 , ... , {N}_{i} .\end{matrix} \qquad Equation 31$$

Linear Stationary Solution

The algorithms dedicated to spectrometric transducers of relatively high resolution may be developed taking into account that the imperfections of a monochromator and of a reference spectrometer used for calibration cannot be neglected. On the other hand, those algorithms may be based on the assumption that neither gₙ(λ) nor αₙ, in Equation 5 depend on n. If, moreover, the assumption of the linear function F(∞; αₙ) is justified, then the mathematical model of the spectrometric transducer 20 and the mathematical model of the chosen reference spectrometer take on the form:
\hat{z}ₙ≡α₀+α₁ŷₙ=[g(λ)*x(λ)]_{λ=λ}_{ₙ} for n=₁, . . . , N Equation 32
\hat{z}_{R,n}≡α_{R,0}+α_{R,1}ŷ_{R,n}=[g_{R}(λ)*x*λ)]_{λ=λ}_{ₙ} for n=1, . . . , N. Equation 33

By representing g(λ) as a convolution of g_{R}(λ) and an auxiliary function g_{Δ}(λ):
g(λ)=g_{R}(λ)*g_{Δ}(λ) Equation 34
the relationship between the two models becomes:
\hat{z}ₙ=[g_{Δ}(λ)*z_{R}(λ)]_{λ=λ}_{ₙ} for n=1, . . . ,N Equation 35
where:
z_{R}(λ)=g_{R}(λ)*x(λ). Equation 36

Thus, the algorithm of spectrum reconstruction will be a numerical implementation of the following deconvolution formula:
\hat{x}(λ)=DECONV[{\hat{α}₀+\hat{α}₁\tilde{y}ₙ},ĝ_{Δ}(λ)] Equation 37
where: \hat{α}₀, \hat{α}₁, and ĝ_{Δ}(λ) are the estimates of α₀, α₁, and g_{Δ}(λ), obtained during the calibration of the spectrometric transducer 20.

The static calibration of the spectrometric transducer 20 requires the use of two flat-spectrum signals:
x₁^{f,cal}(λ)≡X₁^{f} and x₂^{f,cal}(λ)≡X₂^{f}. Equation 38

Assuming that X₂^{f}=0, the estimates of α₀, and α₁ may be obtained as:

$$\begin{matrix}{\hat{α}}_{1} = \frac{{X}_{1}^{f}}{{\overline{y}}_{1}^{f , cal} - {\overline{y}}_{2}^{f , cal}} and {\hat{α}}_{0} = - {\hat{α}}_{1} {\overline{y}}_{2}^{f , cal} \\ where \text{:} & Equation 39 \\ {\overline{y}}_{1}^{f , cal} = \frac{1}{N} {\sum }_{n = 1}^{N} {\tilde{y}}_{n , 1}^{f , cal} and {\overline{y}}_{2}^{f , cal} = \frac{1}{N} {\sum }_{n = 1}^{N} {\tilde{y}}_{n , 2}^{f , cal} . & Equation 40\end{matrix}$$

The dynamic calibration of the spectrometric transducer 20 requires at least one quasi-monochromatic signal x₁^{cal} (λ) and the acquisition of the corresponding reference data at the output of the spectrometric transducer 20 and at the output of the reference spectrometer: {\tilde{y}_{n,1}^{cal}} and {\tilde{y}_{R,n,1}^{cal}}. The estimate of g(λ) may then be determined by means of an algorithm being a numerical implementation of the following deconvolution formula:
ĝ(λ)=DECOQNVW[{\hat{α}₀+\hat{α}₁^{cal}},{\hat{α}_{R,0}+\hat{α}_{R,1}\tilde{y}_{R,n,1}^{cal}}] Equation 41
where \hat{α}_{R,0} and \hat{α}_{R,1} are to be determined in the same way as \hat{α}₀ and \hat{α}₁ on the basis of the responses of the reference spectrometer to two flat-spectrum signals.
Global Optimization of the Microspectrometer Performance

Assuming that the spectrum x(λ) 15 is parameterized by equidistant sampling, as defined by Equation 3:

$$x ( λ ) ≅ {\sum }_{v = 1}^{N} {x}_{v} sin c ( π \frac{λ - {λ}_{v}}{Δλ} ) . \qquad Equation 42$$

Consequently, the normalized model of the data defined by Equation 25 takes on the form:

$$\begin{matrix}\hat{z} = Gx \\ where \text{:} & Equation 43 \\ {G}_{n , k} = {\int }_{- ∞}^{+ ∞} {g}_{n} ( {λ}_{n} - {λ}^{′} ) \cdot sin c ( π \frac{{λ}^{′} - {λ}_{k}^{″}}{{Δλ}^{″}} ) ⅆ {λ}^{′} \\ for n = 1 , … , N ; \\ k = 1 , … , K . & Equation 44\end{matrix}$$

It follows from this model that the attainable accuracy of spectrum estimation wilt mainly depend onpon three factors:
the uncertainty Δ\tilde{z} of the vector \tilde{z} whose elements are defined by Equation 21;
the uncertainty ΔG of the matrix G whose elements, defined by Equation 44 are subject to the errors resulting from measurement identification of the functions gₙ(λ);
the conditioning number of the matrix G: cond(G)=∥G∥ [symbol] G⁻¹ [symbol] .

The following inequality characterizes this dependence:

$$\frac{‖ Δ x ‖}{‖ x ‖} \leq \frac{cond ( G ) \frac{‖ Δ G ‖}{‖ G ‖}}{1 - cond ( G ) \frac{‖ Δ G ‖}{‖ G ‖}} + cond ( G ) \frac{‖ Δ \tilde{z} ‖}{‖ \tilde{z} ‖} \qquad Equation 45$$

provided [symbol] G⁻¹ [symbol] ∥ΔG∥<1. (for any consistent pair of vector and matrix norms).

The right-hand side of the inequality defined by Equation 45 should be taken into account as a criterion for global optimization of spectrometric transducer 20 design.

### INDUSTRIAL APPLICABILITY

It should be noted that the presented general methodology of numerical data processing, dedicated to the integrated microspectrometer 10, takes into account both random and systematic imperfections of the spectrometric transducer 20, including its nonlinearity and variability of its optical responses along the wavelength axis. This variability is of particular importance if the so-called multi-order effects in the optical part of the spectrometric transducer 20 cannot be neglected. Their presence may be modeled by the multimodal functions gₙ(λ), i.e. the functions having more than one maximum. The principal order is represented by a zero-centered peak, and higher and lower orders are represented by additional peaks whose positions are varying with the wavelength (n). The only change implied by this fact is the more complicated structure of the matrix G in Equation 43, sometimes resulting in worse ill-conditioning of the problem of spectrum reconstruction.

The following references address aspects of one or more embodiments described herein, and are hereby incorporated by reference:
[1] R. Z. Morawski, A. Podgdrski: “Methodology of Investigation of the Algorithms for Reconstruction of Thermokinetics”, Bull. Pol Acad. Sci.—Ser. Tech, Sci., 1983, Vol. 31, No. 1-12, pp. 65-69.
[2] R. Z. Morawski: “On reconstruction of Measurement Signals with Discontinuities”, Proc. 5th Int. IMEKO-TC7 Symp. Intell. Meas. (Jena, GDR Jun. 10-14, 1986), Plenum Pub., 1987, pp. 257-260.
[3] R. Z. Morawski: “On Initial-condition Problem in Measurement Signal Reconstruction”, Proc. 6th, IMEKO-TC7 Int. Symp. (Budapest Hungary Jun. 10-12, 1987), pp. 47-52.
[4] R. Z. Morawski, A. Podgórski: “Results of Investigation of Numerical Properties of an Algorithm for Reconstruction of Thermokinetics”, Raporty Instytutu Radioelektroniki Politechniki Warszawsiej, zeszyt 68, Warszawa 1984.
[5] R. Z. Morawski: “Metody odtwarzania sygnalów pomiarowych”, Metrologia i Systemy Pomiarowe—Monografte, zeszyt 1, KMiAN PAN, Warszawa 1989 (wyd. 1), 1990 (wyd. 2), stron 120.
[6] M. Ben Slima, R. Z. Morawski., A. Barwicz: “A Recursive Spline-based Algorithm for Spectrophotometric Data Correction”, Rec. IEEE Instrum. & Meas. Technol. Conf.—IMTC'93 (Irvine, USA, May 18-20, 1993), pp. 500÷503.
[7] D. Massicotte, R. Z. Morawski., A. Barwicz: “Efficiency of Constraining the Set of Feasible Solutions in Kalman-filter-based Algorithms of Spectrophotometric Data Correction”, Rec. IEEE Instrum. & Meas. Technol. Conf.—IMTC'93 (Irvine, USA, May 18-20, 1993), pp. 496-499.
[8] P. Brouard, R. Z. Morawski., A. Barwicz: “Approximation of Spectrogrammes by Cubic Splines Using the Kalman Filter”, Proc. 1993 Canadian Conference on Electrical & Computer Engineering (Vancouver, Canada, Sep. 14-17, 1993), pp. 900-903.
[9] P. Brouard, R. Z. Morawski, A. Barwicz: “DSP-based Correction of Spectrograms Using Cubic Splines and Kalman Filtering”, Record of IEEE Instrum. & Meas. Technol. Conf.—IMTC'94 (Hamamatsu, Japan, May 10-12, 1994), pp. 1443÷1446.
[10] D. Massicotte, R. Z. Morawski, A. Barwicz: “Incorporation of a Positivity Constraint into a Kalman-filter-based Algorithm for Correction of Spectrometric Data”, IEEE Trans. Instrum. & Meas., February 1995, Vol. 44, No. 1, pp. 2-7.
[11] M Ben Slima, R. Z. Morawski, A. Barwicz: “Kalman-filter-based Algorithms of Spectrophotometric Data Correction—Part II: Use of Splines for Approximation of Spectra”, IEEE Trans. Instrum. & Meas., June 1997, Vol. 46, No. 3, pp. 685-689.
[12] L. Szczeciński, R. Z. Morawski, A. Barwicz: “Spectrometric Data Correction Using Recursive Quadratic Operator of Measurand Reconstruction”, Proc. Int. Conf. on Signal Processing Applications & Technology—ICSPAT'95 (Boston, USA, Oct. 24-26, 1995), pp. 588-592.
[13] L. Szczeciński, R. Z. Morawski, A. Barwicz: “Quadratic FIR Filter for Numerical Correction of Spectrometric Data”, Proc. IEEE Instrum. & Meas. Technol. Conf.—IMTC'96 (Brussels, Belgium, Jun. 4-6, 1996), pp. 1046-1049.
[14] L. Szczeciński, R. Z. Morawski, A. Barwicz: “A Cubic FIR-type Filter for Numerical Correction of Spectrometric Data”. IEEE Trans. Instrum. & Meas., August 1997, Vol. 46, No. 4, pp. 922-928.
[15] L. Szczeciński, R. Z. Morawski, A. Barwicz: “Numerical Correction of Spectrometric Data Using a Bilinear Operator of Measurand Reconstruction”. Instrum. Sci. & Technol., 1997, Vol. 25, No. 3, pp. 197-205.
[16] L. Szczeciński, R. Z. Morawski, A. Barwicz: “Numerical Correction of Spectrometric Data Using a Rational Filter”, J. Chemometrics, Vol. 12, issue 6, 1998, pp. 379-395.
[17] M. Wiśniewski, R. Z. Morawski, A. Barwicz: “Using Rational Filters for Digital Correction of a Spectrometric Microtransducer”, IEEE Trans. Instrum. & Meas., Vol. 49, No. 1, February 2000, pp. 4348.
[18] M. P. Wiśniewski, R. Z. Morawski, A. Barwicz: “An Adaptive Rational Filter for Interpretation of Spectrometric Data”, IEEE Trans. Instrum. & Meas., 2003 (in press).
[19] P. Sprz [symbol] czak, R. Z. Morawski: “Calibration of a Spectrometer Using a Genetic Algorithm”, IEEE Trans. Instrum. & Meas., Vol. 49, No. 2, April 2000, pp. 449-454.
[20] P. Sprz [symbol] czak, R. Z. Morawski: “Cauchy-filter-based Algorithms for Reconstruction of Absorption Spectra”, IEEE Trans. Instrum. & Meas., Vol. 50, No. 5, October 2001, pp. 1123-1126.
[21] P. Sprz [symbol] czak, R. Z. Morawski: “Cauchy Filters versus Neural Networks when Applied for Reconstruction of Absorption Spectra”, IEEE Trans. Instrum. & Meas., Vol. 51, No. 4, August 2002, pp. 815-818.

Although the present invention has been described by way of a particular embodiment an example thereof, it should be noted that it will be apparent to persons skilled in the art that modifications may be applied to the present particular embodiment without departing from the scope of the present invention.

I claim:

1. A method for obtaining higher resolution spectral data on lower-resolution spectral data provided by a spectrometric transducer, comprising:
calibrating the spectrometric transducer to produce results for a reconstruction of spectra using the results;
processing the lower-resolution spectra data using a set of numerical algorithms dedicated to an integrated micro-spectrometers associated with the spectrometric transducer and using the results of calibrating to provide the higher resolution spectra data.
